(19) United States
(12) Patent Application Publication
(10) Pub. No.: US 2012/0044628 A1
(43) Pub. Date: Feb. 23, 2012

(54) CONTAINER LOCKING MECHANISM

(76) Inventor: Mark R. Marriott, Leicestershire (GB)

(21) Appl. No.: 13/318,449

(22) PCT Filed: Apr. 30, 2010
(86) PCT No.: PCT/US10/33124

§ 371 Date: Nov. 1, 2011

Related U.S. Application Data
(60) Provisional application No. 61/174,587, filed on May 1, 2009.

(51) Int. Cl. H05K 7/00

(52) U.S. Cl. 361/679.33

(57) ABSTRACT

An apparatus for holding information storage media, such as a CD or DVD, in combination with a releasable security member insertable into the apparatus for inhibiting removal of the storage media from the apparatus, e.g. by inhibiting access to the storage media by locking the apparatus in a closed configuration and/or by locking the storage media to the apparatus. The apparatus comprises a base portion and a lid portion hingedly attached together along a first edge. A reinforcing rib is provided along a second edge opposite from the first edge.

### REFERENCE TO RELATED APPLICATION

This application claims the benefit of priority under 35 U.S.C. §119(e) of provisional application Ser. No. 61/174,587 filed on May 1, 2009, which is hereby incorporated by reference in its entirety.

### BACKGROUND

This invention relates to a container and containers for holding and enclosing a product and to security devices for use therewith to prevent or deter theft.

The invention is particularly concerned with container and containers for products such as compact discs (CDs) or digital versatile discs (DVDs), but may be applicable to other forms of product.

### DESCRIPTION

This invention relates to apparatus and cases for holding and enclosing information storage media and to security devices for use therewith to prevent or deter theft.

The invention is particularly concerned with apparatus and cases for holding disk shaped data carriers, for example CDs and DVDs, but may be applicable, to other forms of information storage media.

Various types of containers are known for holding CDs or DVDs. Many CDs are housed in so called “jewel boxes” which comprise a plastic tray on which the CD is mounted and the tray is installed within a clear plastic box comprising a base portion and a lid portion hinged thereto. More recently there have been advances in the technology, particularly for housing DVDs, which are described in U.S. Pat. No. 5,788,068, the disclosure of which is incorporated herein by reference.

A problem encountered with such known apparatus is the removal and theft of a CD or DVD from the apparatus within a store selling such products. The disk holder is usually provided within a container which is provided with a security tag which triggers an alarm if the container is taken out of the store without the tag first being removed or rendered inactive by staff in the store. The container may also be provided with a clear plastic wrapper which has to be removed before the container can be opened. However, it has been found that thieves are able to slit the wrapper along an edge of the container, e.g. the bottom edge, and release the CD or DVD from the disk holder within the container by actuating the release mechanism thereof by pressing this through a side wall of the container. They are then able to remove the CD or DVD from the container by compressing the container so that the side walls bow forming a gap between the two halves thereof so the CD or DVD can be slid out through the slit made in the wrapper. An experienced thief is able to do this whilst pretending to examine the product and slip the CD or DVD into a coat pocket unobserved. They then leave the empty container on the shelf and leave the store with the CD or DVD in their pocket without triggering the alarm system.

In U.S. Pat. No. 7,404,484 (the '484 patent, which is incorporated by reference herein), a case is disclosed, which, among other functions, may hold information storage media in combination with a releasable security member insertable into the case for inhibiting removal of the storage media from the case. The releasable security member may also hold the case closed.

The apparatus disclosed in the '484 patent may be adapted to hold disc-shaped data carriers such as compact discs (CDs) or DVDs. The security device can be used with a wide variety of such apparatus including CD or DVD cases as described in U.S. Pat. No. 5,788,068 and the well-known version of a CD case known as a “jewel box.”

The present disclosure relates to an improvement on the apparatus of the '484 patent.

Preferred and optional features of the invention will be apparent from the following description and from the subsidiary claims of the specification.

The invention will now be further described, merely by way of example, with reference to the accompanying drawings, in which:

### BRIEF DESCRIPTION OF DRAWINGS

FIG. 1 is a plan view of an apparatus for holding a DVD, together with a schematic representation of a security device partially inserted therein;

FIG. 2 is a plan view of the apparatus of FIG. 1, with a strengthening rib added;

FIG. 3A is a perspective view the apparatus of FIG. 2;

FIG. 3B is a detail of the apparatus of FIG. 3A;

FIG. 4A is a perspective view of another embodiment of the apparatus; and

FIG. 4B is a detail of the apparatus of FIG. 4A.

### DETAILED DESCRIPTION

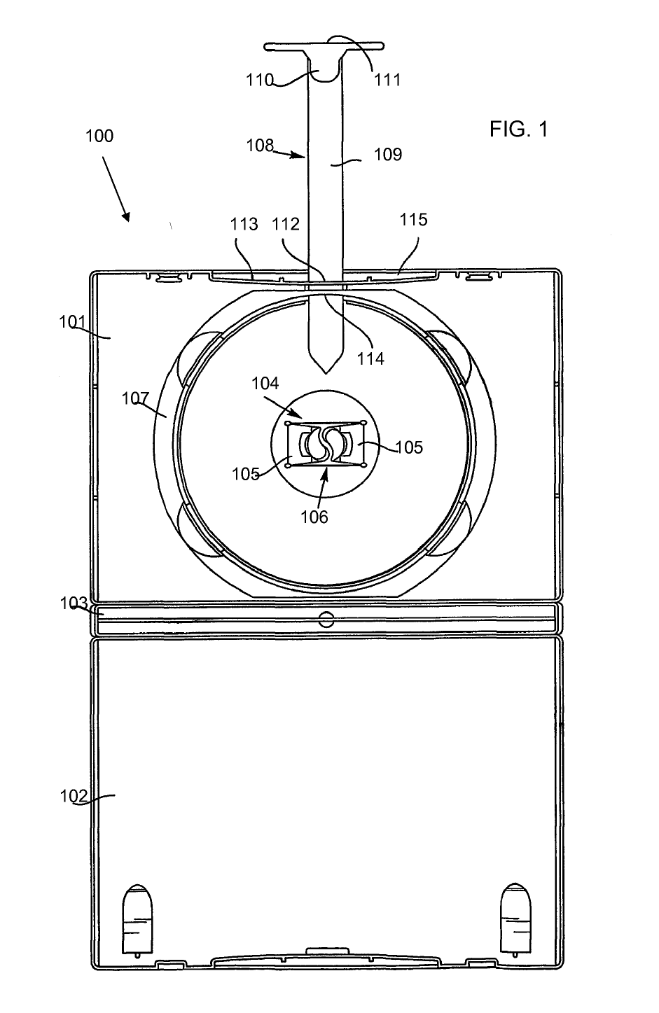

FIG. 1 shows a known apparatus 100 for holding a disk shaped information storage media such as a DVD. The apparatus comprises a base portion 101 and a lid portion 102 connected by a hinge portion 103. A disk engaging mechanism 104 is provided on the base portion 101 for releasably engaging the central aperture of a DVD or CD The mechanism preferably comprises at least one cantilevered arm 105 with a button-like member 106 at the radially inner end thereof. The example shown comprises two cantilevered arms each having a button portion at its inner end.

An upstand 107 is provided on the base portion so as to extend around the periphery of a disk mounted in the apparatus.

The apparatus operates in the manner described in U.S. Pat. No. 5,788,068 and referred to above. This will not be described further here other than to note that to release a disk from the apparatus, the button portions 106 and the arms 105 on which they are provided must be depressed. Accordingly, by inserting a security device 108 beneath the arms 105 when the disk is in place, the disk can be locked on the button 106. This is described further in the PCT patent application no. PCT/GB01/04553 the disclosure of which is also incorporated herein.

The security device 108 shown in FIG. 1 comprises a first long arm 109 and a second, shorter arm 110 the two arms being connected to a head 111. The two arms 109, 110 and the head 111 each comprises a flat strip of a relatively tough plastic material, e.g. glass reinforced NYLON™ or ABS each being approximately 8-12 mm wide and 1.0 to 1.5 mm thick.

The long arm 109 passes through a slot 112 in a side wall 113 of the base portion and through a slot 114 in the upstand 107 so that it can extend across the base portion 101 and be fitted beneath the arms 105 in order to prevent operation of the disk release mechanism 104.

FIG. 1 shows the security device 108 partially inserted in the apparatus. Once the lid 102 of the case is moved to the closed position, the security device 108 is pushed further in the case so that the head 111 lies within a recess 115 in the edge of the case (this recess being provided to facilitate finger access to the opening edge of the case) and the shorter arm 110 passes through a slot in the edge of the lid portion 102 so as to hold the lid 102 in the closed position, as will be described further below.

The security device 108 can be locked in place in a variety of ways depending upon the level of security required. In a simple form, requiring only a low level of security, the security device 8 may be inserted into the case to lock the disk release mechanism 108 and to hold the case closed and the case then provided with a wrapping (not shown), e.g. a clear plastics sleeve or shrink wrapping, passing over the recess 115 so the device 108 can only be removed following breakage or removal of this wrapping.

In addition, a conventional security tag (not shown) can be mounted on the longer arm 109 (or the shorter arm 110 if it is big enough) so it cannot be removed without withdrawing the device 108 from the case. Alternatively, the security tag can be mounted on the inner face of the head 111 or positioned such that it is sandwiched between the head 111 and the side wall 113 of the case when the device 108 is fully inserted within the case so, again, it cannot be removed without withdrawing the device 108 from the case.

It will be appreciated that the security member 108 described above is slidable through an aperture, e.g. the slot 112, in an edge of the case opposite the hinge portion 103. The security member is thus located in the opening edge of the case opposite the hinge where it is most effective in holding the case closed. A user normally opens such a case by prising apart the base and lid portions along the edge opposite the hinge as this give maximum leverage and both portions can be easily engaged by the user's fingers or thumbs. It is for this reason, the finger recess 115 is provided in this position. The security member 108 being inserted in this edge thus holds the case closed at the point where such opening forces would normally be applied. It can also be designed to inhibit access to the edges of the base and lid portion where they are normally prised apart. Location of the security member in this edge also enables the security member 108 to be made small particularly if it is not designed to extend to the disk engaging mechanism 104, but even if it also provides this function, this is the shortest route to the disk release mechanism (for a rectangular DVD box of the type illustrated). The security member preferably slides through an aperture in the edge of the case in a direction towards the hinge portion 103.

The effectiveness of the apparatus for securing and protecting the contents, such as a DVD, relies to some extent on the strength of the materials from which the apparatus is made. For example, the thickness of base portion 101, lid portion 102, and hinge portion 103 each have an influence on the strength of the apparatus. In particular, when the security member 108 holds the apparatus closed along the center, the stiffness of the base portion 101 and lid portion 102 help hold closed the corners of the apparatus. In order to reduce the amount of material, such as plastic, used in the apparatus, it may be desirable to use a thinner base portion 101 and lid portion 102. This may reduce the stiffness of the base portion, and particularly, the lid portion. Base portion 101 gains some stiffness from the material in upstand 107. However, lid portion 102 may lack such features.

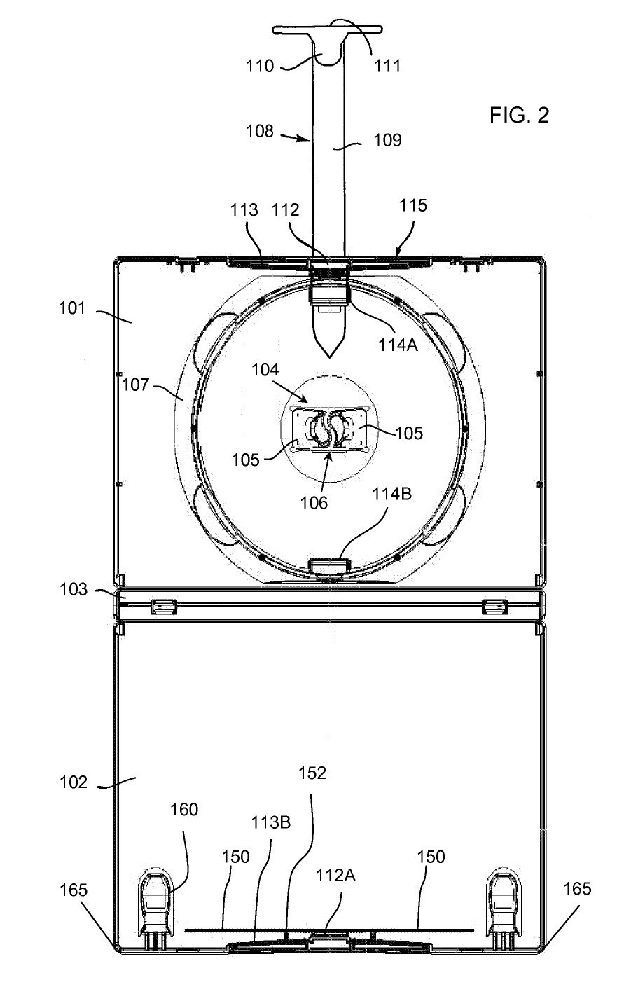

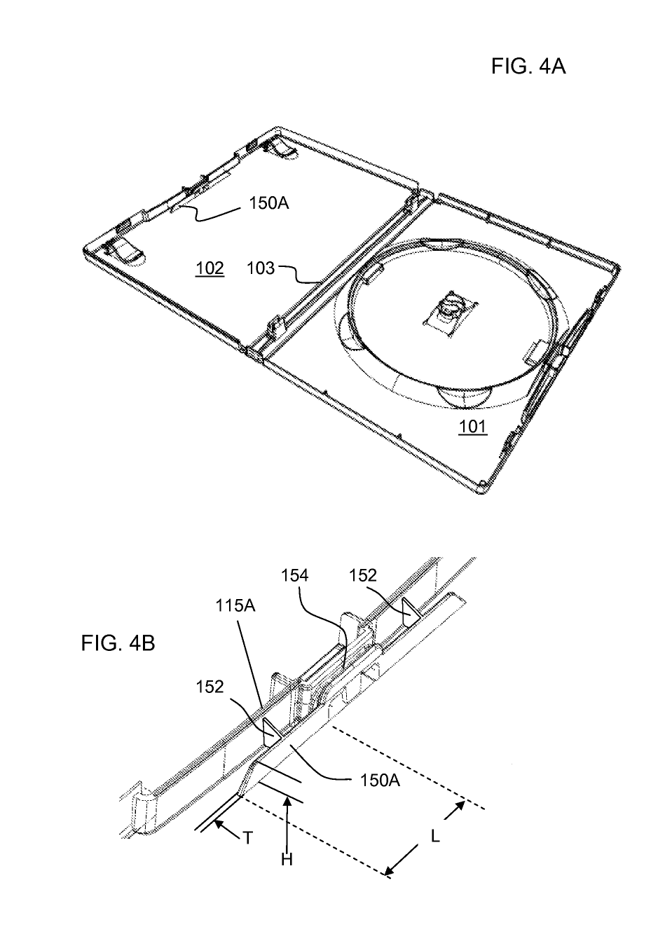

FIG. 2 shows another apparatus for holding a disk. While similar in many respects to the apparatus shown in FIG. 1, certain aspects are different as will be described here. In the base portion 101, slot 114A through upstand 107 in this instance may be extended inward slightly in the form of a short tunnel. A terminal slot 114B may be provided on the hinge side of the apparatus, for receiving the end of long arm 109. In the lid portion 102, a reinforcing rib 150 may be provided extending from the lid slot 112A (through which short arm 110 passes to hold the apparatus closed) or other structure through which security member 108 passes, and outward toward corners of the apparatus. When security member 108 is the apparatus, reinforcing rib 150 may serve to extend the clamping strength of the security member outward from the center of the apparatus and toward the adjacent corners 165. The reinforcing rib 150 may be attached to lid portion side wall 113A by one or more buttresses 152 (more clearly seen in FIG. 4B). Reinforcing rib 150 may extend outward to adjacent corner 165, extending for example as far or nearly as far as literature clip 160, or even further if no literature clip is provided. Reinforcing rib 150 may also extend a lesser distance. There may be one, two, or more reinforcing ribs extending outward to each of adjacent corners 165.

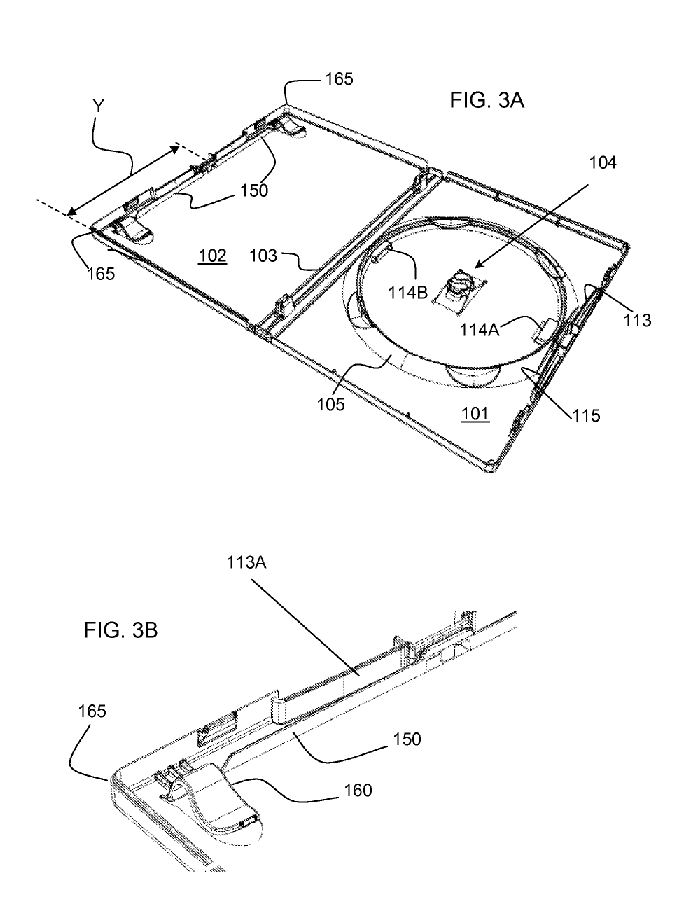

FIG. 3A shows a perspective view of the apparatus of FIG. 2, including rib 150, while FIG. 3B shows a close-up detail of rib 150, lid portion side wall 113A, and literature clip 160. In this example, rib 150 extends outward almost reaching the literature clip. FIGS. 4A and 4B show corresponding perspective and detail views of another embodiment of the apparatus including a rib 150A that extends a shorter distance outward.

The rib 150, 150A may add strength to the lid. The strengthening effect of rib 150, 150A may be adjusted by modifying the length L, thickness T, and height H of the rib. The thickness T and height H may vary along the length L. There may be two or more ribs, for example, one rib extending outward toward each of adjacent corners 165. Two or more ribs, of equal or different sizes, may extend approximately parallel toward one or each of adjacent corners 165. Any combination of ribs may be used, for example a single rib extending to one corner, a first rib extending to one corner and a second rib extending to the other corner, two ribs extending to one corner and two other ribs extending to the other corner, two ribs extending to one corner and three ribs extending to the other corner, etc. Ribs extending toward opposite corners may be connected or partly connected to one another at or near slot 112.

By way of example, the length L of each rib may range from about 1 cm to about 6 cm on a DVD case with literature clips, or from about 1 cm to about 8 cm on a DVD case without literature clips 160. For other size cases, the length of each rib 150, 150A may range from about 10% to about 90% of the distance “Y” between the lid slot 112A and the adjacent corner 165. The thickness T of the rib may, for example, range from about 0.5 mm to about 5 mm. The height H of the rib may, for example, range from about 1 mm to about 5 mm. The thickness T and height H of the rib may vary across its length L.

There may be provided a tapered or sloped termination at the ends of the rib. The rib 150, 150A may be attached to the lid portion side wall 113A by one or more web 154.

Buttresses 152 may be used to connect rib 150, 150A and lid portion side wall 113A. The number and size of such buttresses may vary from the example shown in FIG. 4B. Such buttresses may be located at one or more locations anywhere along the length of the rib 150, 150A. If two or more ribs extend toward one corner, those ribs may be connected by one or more buttresses between the ribs.

It will be appreciated from the above that this invention can be provided in various different forms. Many of the individual features and combinations of features referred to above are believed to be novel. The invention is thus not limited to the specific combinations of features or the embodiments described but extends to cover each of the principles described or combinations thereof.

Whilst the invention has been described in relation to a disk holder of the type shown in the drawings, it will be appreciated that such disk holders can take a variety of forms and many aspects of the invention can be used with other types of disk holder.

Furthermore, as indicated in the introduction, aspects of the invention are also applicable to an apparatus or case for holding other types of information storage media, or products other than information storage media.

The invention claimed is:

1. Apparatus for use in holding information storage media, the apparatus comprising:
a base portion;
a lid portion;
whereby the base portion and lid portion are hingedly attached together along a first edge of the apparatus, and moveable relative to each other between open and closed positions, and
a reinforcing rib located on at least one of the base portion and the lid portion and proximate to a second edge of the apparatus that is opposite from the first edge of the apparatus.

2. The apparatus of claim 1, further comprising a releasable security member comprising a first projection and a second projection both extending from a head portion in a first direction, the base portion being adapted to receive the first projection and the lid portion being adapted to receive the second projection so that, when the first and second projections are respectively received by the base and lid portions, the base and lid portions are thereby held in the closed position with the head portion located adjacent an external surface of the apparatus.

3. The apparatus as recited in claim 1 comprising a holding member on the base portion for releasably holding information storage media; the releasable security member being insertable into the base portion so as to interact with the holding member to inhibit the holding member from releasing the information storage media.

4. The apparatus as recited in claim 1 in which the head portion of the security member fits within a recess in the exterior of the apparatus when the first and second projections are received by the base and lid portions.

5. The apparatus as recited in claim 1 wherein the reinforcing rib extends substantially parallel to the second edge of the apparatus.

6. The apparatus as recited in claim 1 wherein the reinforcing rib comprises a length between 1 cm and 6 cm.

7. The apparatus as recited in claim 1, wherein the reinforcing rib comprises a thickness between 0.5 mm and 5 mm.

8. The apparatus as recited in claim 1, wherein the reinforcing rib comprises a height between 1 mm and 5 mm.

9. The apparatus as recited in claim 1, wherein the reinforcing rib and at least one of the base and lid are made from the same material.

10. The apparatus as recited in claim 1, comprising two reinforcing ribs, each rib extending in opposite directions along the second edge.

11. The apparatus as recited in claim 1, further comprising a buttress between the reinforcing rib and the second edge.

12. The apparatus as recited in claim 1, further comprising a second reinforcing rib proximate to and substantially parallel to the reinforcing rib.

13. The apparatus as recited in claim 12, further comprising a buttress between the reinforcing rib and the second reinforcing rib.
